(19) United States
(12) Patent Application Publication
(10) Pub. No.: US 2015/0223369 A1
(43) Pub. Date: Aug. 6, 2015

(54) ELECTROSTATIC PROTECTION ELEMENT AND METHOD FOR MANUFACTURING SAME

(71) Applicant: TATEYAMA KAGAKU INDUSTRY CO., LTD., Toyama-shi, Toyama (JP)

(72) Inventors: Keisuke Otsubo, Toyama (JP); Yoshiyuki Takano, Toyama (JP); Ryoichi Murata, Toyama (JP)

(73) Assignee: TATEYAMA KAGAKU INDUSTRY CO., LTD., Toyama-shi, Toyama (JP)

(21) Appl. No.: 14/419,927

(22) PCT Filed: Jul. 30, 2013
(86) PCT No.: PCT/JP2013/070570

§ 371 Date: Feb. 5, 2015

(30) Foreign Application Priority Data
Aug. 9, 2012 (JP) 2012-176964

(51) Int. Cl. H05K 9/00; H01T 21/00; H01T 4/02; H01T 1/24; H01T 4/10

(52) U.S. Cl. CPC H05K 9/0067; H01T 1/24; H01T 4/10; H01T 4/02; H01T 21/00; H05K 9/0079

(57) ABSTRACT

An electrostatic protection element is provided with: a pair of discharge electrodes that are provided on an insulating substrate; and a discharge auxiliary electrode that connects the discharge electrodes to each other so as to link a discharge gap D between the discharge electrodes. The discharge auxiliary electrode has a varistor function with zinc oxide as a main component, and is formed by thick-film printing. The electrostatic protection element is provided with an insulating dome-forming layer with which a cavity portion is formed so as to cover the discharge gap D. The dome-forming layer is formed of glass ceramics, and is coated with a protection layer. The electrostatic protection element is capable of stably achieving a sufficient electrostatic protection function, and has a low electrostatic capacitance and a low discharge start voltage.

### TECHNICAL FIELD

The present invention relates to an electrostatic protection element to protect an IC in an electronic circuit and an element in the IC against an overvoltage due to an electrostatic discharge and a method for manufacturing the electrostatic protection element.

### BACKGROUND ART

In recent years, due to miniaturization and higher performance as well as higher transmission speed and lower driving voltage of electronic devices, the withstand voltage of electronic parts used in the electronic devices is lowering. Accordingly, when a human body makes contact with a terminal of an electronic device, electrostatic pulses that are generated in the human body flow through the electronic device, and protecting electronic parts against an overvoltage therefrom poses an important technological challenge.

Conventionally, in order to protect electronic parts against such an overvoltage, a countermeasure is generally taken to provide a varistor between a line and a ground, where the overvoltage is applied. However, an electrostatic protection element using a conventional varistor has a large electrostatic capacitance with a low discharge start voltage, and thus the electrostatic protection element has not served as an effective countermeasure for small and high-performance electronic devices and communication devices. On the other hand, there also sexists a discharge-type element specialized for having a smaller electrostatic capacitance to respond to higher transmission speed, however, the smaller electrostatic capacitance has resulted in a higher discharge start voltage, therefore the discharge-type element has not been suitable for the small and high-performance electronic devices.

Thus, there has been an element as disclosed in Patent Literature 1 as an ESD (Electrostatic Discharge) countermeasure part having a low discharge start voltage. This element includes a thermosetting resin cured product layer that is provided on an insulating ceramic substrate, and a cavity is provided on an interface between the thermosetting resin cured product layer and the insulating ceramic substrate. Included on the insulating ceramic substrate are: first and second discharge electrodes provided such that the edges oppose each other with a gap therebetween where the gap is exposed to a cavity; and a discharge auxiliary electrode that is provided to electrically connect the first and second discharge electrodes. The discharge auxiliary electrode is formed with a material including a metal particle of which the surface is coated by an inorganic insulating material powder, and ceramics.

Further, as disclosed in Patent Literatures 2 and 3, material powder in which the surfaces of particles made of an insulating inorganic material are coated with a conductive inorganic material, and an electrostatic protection element using the material powder are proposed as a functional film material for electrostatic protection that forms a low electrostatic capacitance element. This electrostatic protection element includes a substrate having an insulating surface, electrodes arranged to oppose and separate from each other on the insulating surface, and a functional layer arranged at least between the electrodes, in which the functional layer includes a composite particle having an electrically conductive inorganic particle of which the surface is electrically conductive and a coat made of an insulating inorganic material formed on at least a part of the periphery of the electrically conductive inorganic particle.

In addition, as disclosed in Patent Literature 4, a static-electricity countermeasure element is also proposed in which a discharge induction unit having a hollow portion (a cavity portion) is formed between a pair of electrodes. In this static-electricity countermeasure element, the discharge induction unit is made of a porous body having micropores scattered discontinuously, and the insulating inorganic material and an electrically conductive inorganic material are scattered discontinuously. The insulating inorganic material includes metallic oxide such as aluminum oxide, SiC and the like. The electrically conductive inorganic material includes a metal, an alloy and the like.

An ESD protection device disclosed in Patent Literature 5 includes a discharge auxiliary electrode in which a Cu particle and a silicon carbide particle are bonded via vitreous between a pair of electrodes and the pair of electrodes and the discharge auxiliary electrode are covered with a cavity portion enclosed by a sealing layer made of ceramics particles. The sealing layer is a porous layer, and has a function of absorbing a glass component included in a ceramics material in a porous part in a firing step to prevent the glass component from flowing into the discharge auxiliary electrode.

### CITATION LIST

### Patent Literature

[PTL 1] Japanese Unexamined Patent Application Publication No. 2011-243492

[PTL 2] Japanese Unexamined Patent Application Publication No. 2011-204443

[PTL 3] Japanese Unexamined Patent Application Publication No. 2011-204855

[PTL 4] International Publication WO2012/043576

[PTL 5] International Publication WO2011/040437

### SUMMARY OF THE INVENTION

### Problems to be Solved by the Invention

However, it has required dedicated facilities to manufacture the inorganic material powder that is provided with the coat made of the insulating inorganic material on the periphery of the electrically conductive inorganic particle such as a metal particle, which is used for the elements disclosed in Patent Literatures 1 to 3, and hence costly. Moreover, there has been a problem that this inorganic material powder is hard to discharge at around several tens of V to 100 V, and has a high discharge start voltage as an electrostatic protection element in which electrostatic protection at a low voltage is required. Further, the glass component of the electrode material arranged to oppose each other is coated on an electrode surface to inhibit the starting of discharge between the electrodes, and the inhibition also has increased the discharge start voltage.

The discharge induction unit having the hollow portion, of the static-electricity countermeasure element disclosed in Patent Literature 4 is made of the porous body having micropores scattered discontinuously, and the insulating inorganic material and the electrically conductive inorganic material are scattered discontinuously, in which the insulating inorganic material includes metallic oxide such as aluminum oxide and SiC, and the metal particle is used as the electrically conductive inorganic material. This discharge induction unit is only provided between a pair of electrodes, and the discharge start voltage is 2 to 3 kV, which may not be a low value.

The discharge auxiliary electrode of the ESD protection device disclosed in Patent Literature 5 is one in which a Cu particle and a silicon carbide particle are bonded via vitreous, the sealing layer that forms the cavity portion is a porous ceramics layer, and has a function of absorbing a glass component included in a ceramics material in a porous part in a firing step to prevent the glass component from flowing into the discharge auxiliary electrode. The discharge property of this element is 0.2 kV even at the lowest voltage in a test, and still high as a discharge start voltage required in the invention of the present application.

The present invention has been devised in view of the background art described above, and an object thereof is to provide an electrostatic protection element having a low electrostatic capacitance and a low discharge start voltage, capable of stably achieving a sufficient electrostatic protection function with a simple configuration for small and high-performance electronic devices and electronic devices used for high-speed communication, and a method for manufacturing the electrostatic protection element.

### Means for Solving the Problem

The present invention is an electrostatic protection element, comprising: a pair of discharge electrodes that are provided on an insulating substrate with a discharge gap of 30 to 200 μm therebetween; a discharge auxiliary electrode that connects the discharge electrodes to each other so as to link the discharge gap between the discharge electrodes, has a varistor function with zinc oxide as a main component, and is provided by thick-film printing; and an insulating dome-forming layer with which a cavity portion is formed so as to cover the discharge gap.

The discharge auxiliary electrode has zinc oxide as a main component, and is made of ceramics powder including 0.7 to 10 mol % of at least two types of the respective oxides of cobalt, nickel, chromium, praseodymium, aluminum, antimony, bismuth, manganese, and titanium.

In addition, the present invention comprises: a pair of porous films of ceramics that are provided on an insulating substrate by thick-film printing with a 30 to 200 μm gap therebetween; a pair of discharge electrodes that are provided to be laminated on the porous films with a discharge gap therebetween where the discharge gap is wider than the gap; and an insulating dome-forming layer with which a cavity portion is formed so as to cover the discharge gap. Each of the porous films is made of ceramics and made of at least one of aluminum oxide, zinc oxide, strontium oxide, titanium oxide, magnesium oxide, silicon carbide, aluminum carbide, molybdenum carbide, zirconium carbide, titanium boride, and zirconium boride.

The dome-forming layer is formed of glass ceramics, and is coated with a protection layer. The glass ceramics is made of alumina and a borosilicate glass component.

Further, this invention is a method for manufacturing an electrostatic protection element, comprising: forming a discharge auxiliary electrode on an insulating substrate by printing and firing a paste of a material of a discharge auxiliary electrode that has a varistor function with zinc oxide as a main component, and is made of ceramics powder including 0.7 to 10 mol % of at least two types of the respective oxides of cobalt, nickel, chromium, praseodymium, aluminum, antimony, bismuth, manganese, and titanium; printing a paste of a material of a pair of discharge electrodes on the discharge auxiliary electrode and on both end portions of the insulating substrate such that a 30 to 200 μm discharge gap overlaps with the discharge auxiliary electrode; firing at a temperature that is lower than a firing temperature of the discharge auxiliary electrode to form a pair of discharge electrodes that are laminated on the discharge auxiliary electrode with the discharge gap therebetween; and providing an insulating dome-forming layer with which a cavity portion is formed so as to cover the discharge gap.

In addition, the present invention is a method for manufacturing an electrostatic protection element, comprising: printing, in a predetermined shape, a paste of ceramics powder that forms a pair of porous films on an insulating substrate with a 30 to 200 μm gap therebetween; firing the paste at a temperature that is lower than the melting point of the ceramics by 100° C. or more and that allows firing to form the pair of porous films, printing a paste of a material of a pair of discharge electrodes that are laminated on the porous films with a discharge gap therebetween wherein the gap is wider than the gap between the edges of the pair of porous films, on the porous films and on the both end portions of the insulating substrate; firing the paste at a temperature that is lower than the firing temperature of the porous films to form a pair of discharge electrodes that are laminated on the porous films with a discharge gap therebetween, and providing an insulating dome-forming layer with which a cavity portion is formed so as to cover the discharge gap.

The cavity portion is formed by providing and curing a resin material so as to cover the gap between the discharge electrodes, applying a forming material of the dome-forming layer on the resin material, firing the forming material at a temperature that is lower than the firing temperature of the discharge electrodes, and evaporating the resin material.

The dome-forming layer is made by printing and firing a paste of glass ceramics on the resin material.

### Effect of the Invention

The electrostatic protection element of the present invention has an extremely low discharge start voltage, operates stably, and also has a small electrostatic capacitance. Accordingly, the electrostatic protection element can securely protect small electronic devices, circuits used for high-speed communication, and other ICs, and also does not deteriorate performance of electronic devices, communication quality and the like. Further, a manufacturing process is simple, manufacturing is easy, and also costs can be reduced.

In addition, in the method for manufacturing the electrostatic protection element of the present invention, an electrostatic absorber and each of layers that are laminated thereon can be formed by a printing step, and a thick-film printing method enables easy production of an electrostatic protection element having an extremely low discharge start voltage and also a small electrostatic capacitance.

### BRIEF DESCRIPTION OF THE DRAWINGS

FIG. 1 is a vertical cross-sectional view of an electrostatic protection element according to a first embodiment of the present invention.

FIGS. 2(a)-(e) are drawings of a schematic section showing a manufacturing process of the electrostatic protection element according to this embodiment.

FIG. 3 is a vertical cross-sectional view of an electrostatic protection element according to a second embodiment of the present invention.

FIGS. 4(a)-(e) are drawings of a schematic section showing a manufacturing process of the electrostatic protection element according to this embodiment.

### BEST MODES FOR CARRYING OUT THE INVENTION

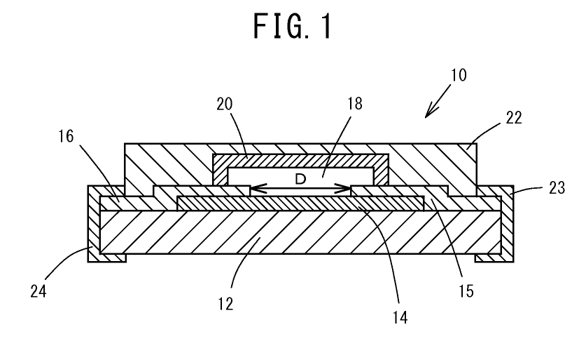

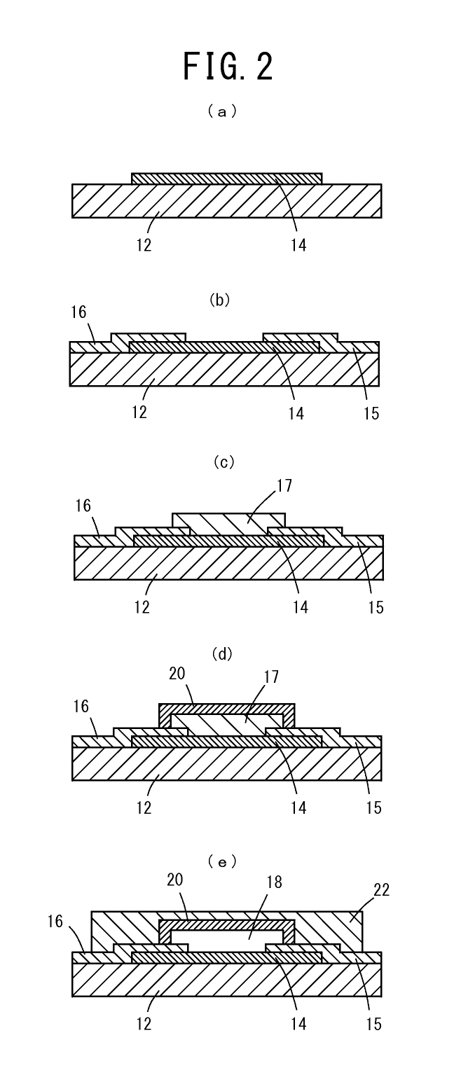

The embodiments of the present invention will hereinafter be described. Each of FIG. 1 and FIGS. 2(a)-(e) shows an electrostatic protection element 10 of a first embodiment of the present invention. This electrostatic protection element 10 is a surface-mounted chip-type element, made of alumina of 96% purity, for example, and a tabular and rectangular insulating substrate 12 is used in the electrostatic protection element 10. On the insulating substrate 12, a discharge auxiliary electrode 14 is provided from the center portion to the both end portions of a surface in a length from around ½ to ¾ of the total length appropriately. The discharge auxiliary electrode 14 has a varistor function, has zinc oxide (ZnO) as a main component, and includes 0.7 to 10 mol % of at least two types of the respective oxides of cobalt (Co), nickel (Ni), chromium (Cr), praseodymium (Pr), aluminum (Al), antimony (Sb), bismuth (Bi), manganese (Mn), and titanium (Ti). The thickness of the discharge auxiliary electrode 14 is around 5 to 40 μm, and set appropriately depending on an application, a discharge start voltage and the like.

The discharge auxiliary electrode 14 is specifically, for example, a ceramics material containing zinc oxide/cobalt oxide/bismuth oxide in the range of 90 to 99.4 mol %/0.1 to 5.0 mol %/0.5 to 5.0 mol %. In addition, the discharge auxiliary electrode 14 is made of a ceramics material containing zinc oxide/manganese oxide/praseodymium oxide in the range of 90 to 99.4 mol %/0.1 to 3.0 mol %/0.5 to 5.0 mol %, or a ceramics material containing zinc oxide/cobalt oxide/nickel oxide/bismuth oxide in the range of 90 to 99.3 mol %/0.1 to 3.5 mol %/0.1 to 1.5 mol %/0.5 to 5.0 mol %.

From the both end portions of the discharge auxiliary electrode 14 to the both end portions of the insulating substrate 12, a pair of discharge electrodes 15 and 16 are arranged to oppose each other. An opposing interval between the discharge electrodes 15 and 16 in the center portion of the insulating substrate 12 forms a discharge gap D, which is appropriately set to D=around 30 to 200 μm depending on an application, a discharge start voltage and the like. The discharge electrodes 15 and 16 are formed of powder of a precious metal such as Au, Ag, and Pd and a base metal such as Cu and Ni, and a conductor paste containing glass frit. This conductor paste is made of a material that can be fired at a temperature that is lower than a firing temperature of the discharge auxiliary electrode 14, and preferably a material that can be fired at a temperature that is lower by 100° C. or more in a manufacturing process which will be described below, and a conductor paste having, for example, the mass ratio of Ag:Pd=80:20 is used.

The discharge gap D of the pair of the discharge electrodes 15 and 16 is enclosed by a cavity portion 18 that is formed with a dome-forming layer 20. The dome-forming layer 20 is an insulator and is glass ceramics made of alumina and a borosilicate glass component. The cavity portion 18 formed with the dome-forming layer 20 is 15 to 100 μm, preferably around 30 to 50 μm in height, and encloses the whole gap D.

The whole of dome-forming layer 20 is covered with an insulating protection layer 22. The protection layer 22 is formed of glass ceramics or an epoxy resin similar to that of the dome-forming layer 20 and formed on the discharge electrodes 15 and 16 so as to cover a range where the dome-forming layer 20 and the discharge auxiliary electrode 14 are formed.

External electrodes 23 and 24 connected to the discharge electrodes 15 and 16, respectively, are formed on the both end portions of the insulating substrate 12. Nickel plating and solder plating or tin plating or the like are applied on the surface of each of the external electrodes 23 and 24.

A method for manufacturing the electrostatic protection element 10 of this embodiment will now be explained with reference to FIGS. 2(a)-(e). First, a paste for a discharge auxiliary electrode having zinc oxide (ZnO) as a main component to form the discharge auxiliary electrode 14 is produced. A material used in the discharge auxiliary electrode 14 is ceramics powder having zinc oxide (ZnO) as a main component and including 0.7 to 10 mol % of at least two types of the respective oxides of cobalt (Co), nickel (Ni), chromium (Cr), praseodymium (Pr), aluminum (Al), antimony (Sb), bismuth (Bi), manganese (Mn), or titanium (Ti) as described above, and the ceramics powder is mixed with an organic binder to be a paste for thick-film printing adjusted to have viscosity with which screen printing is possible. To form this paste, mixed powder of zinc oxide (ZnO) and an additive material is pulverized more finely by a pulverization device, and resulting fine powder and a vehicle made of an organic binder component are mixed and kneaded to be a paste for thick-film printing.

The insulating substrate 12 is to be divided later into individual insulating substrates 12, and pastes for thick-film printing for a plurality of discharge auxiliary electrodes 14 are applied onto predetermined places on a large multiple-piece insulating substrate by screen printing, as shown in FIG. 2(a). As for an application thickness, printing is performed so that a thickness after firing is a predetermined thickness within 5 to 40 μm.

Thereafter, the insulating substrate 12 is fired at 1050 to 1250° C. for 0.5 to 3 hours. Accordingly, the discharge auxiliary electrode 14 having a desired thickness is formed on the surface of each of the insulating substrates 12.

Next, by using a conductor paste such as Ag—Pd, the conductor paste of an electrode material for the discharge electrodes 15 and 16 is screen-printed to form the discharge electrodes 15 and 16 by printing on the large substrate of the insulating substrate 12, as shown in FIG. 2(b). The conductor paste for the discharge electrodes 15 and 16 is formed with an opposing interval so that the discharge gap D is formed on the discharge auxiliary electrode 14 in the center portion of the insulating substrate 12. Then, firing is performed at 800 to 950° C. to form the discharge electrodes 15 and 16.

The pair of discharge electrodes 15 and 16 are applied with a resin material 17 that is a thermosetting resin material such as ethyl cellulose and PVB to form the cavity portion 18 that encloses the discharge gap D and that evaporates and dissipates at 250 to 700° C., by screen printing, dispensing or the like, as shown in FIG. 2(c). The application thickness of this resin material 17 defines the height of the cavity portion 18 and is applied so as to enclose the whole of the gap D at 15 to 100 μm, and preferably at around 30 to 50 μm. Thereafter, the resin material 17 for forming the cavity portion 18 is cured at 150 to 250° C.

After the resin material 17 for forming the cavity portion 18 is cured, a paste of glass ceramics that forms the dome-forming layer 20 on the resin material 17, is formed so as to cover the whole of the resin material 17 for forming the cavity portion 18, as shown in FIG. 2(d). The glass ceramics paste that forms the dome-forming layer 20 is provided by screen printing. Thereafter, the glass ceramics paste is fired at the temperature of 600 to 850° C. to provide the dome-forming layer 20 with which the cavity portion 18 is formed. At this time, first, a degreasing step of the resin material for forming the cavity portion 18 is performed at 250 to 700° C. to evaporate the resin material for forming the cavity portion 18, and thereafter fire the dome-forming layer 20.

Next, the protection layer 22 is formed with glass ceramics or an epoxy resin so as to cover the dome-forming layer 20 and fired, as shown in FIG. 2(e).

Subsequently, by using horizontal dividing grooves formed on the large substrate, a dividing step of dividing into block units is performed in each of which a series of electrostatic protection elements 10 are laterally arranged in a row. Thereafter, the external electrodes 23 and 24 are formed, by plating or the like, on the divided surfaces of blocks separated by the dividing step and the exposed surfaces of the discharge electrodes 15 and 16 on the insulating substrate 12. Finally, each of the blocks subjected to a dividing process in the dividing step is further divided into individual pieces. Through the steps described above, the chip-type electrostatic protection element 10 is completed. A chip size at this time is, for example, 1.0 mm×0.5 mm.

In the electrostatic protection element 10 and the method for manufacturing same of this embodiment, the discharge auxiliary electrode 14 is located between the discharge electrodes 15 and 16, an electrostatic charge passes through the discharge auxiliary electrode 14, and ESD protection is performed by resistance by a grain boundary of the discharge auxiliary electrode 14 at a low voltage of around several tens of V. On the other hand, the ESD protection is performed by the creeping discharge of the discharge auxiliary electrode 14 at a high voltage.

In addition, in the electrostatic protection element 10 of this embodiment, the discharge auxiliary electrode 14 and the like can be formed in the printing step, the width and the thickness of the electrostatic protection element 10 can be easily adjusted, the manufacturing process is simple, and it is possible to form an element having desired performance in stable quality. Further, in a discharge at a low voltage, since a charge passes through the discharge auxiliary electrode 14, an insulation coating can be omitted, and also at this point, manufacturing costs can be reduced.

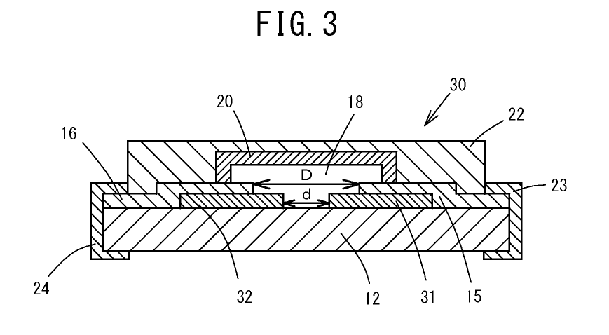

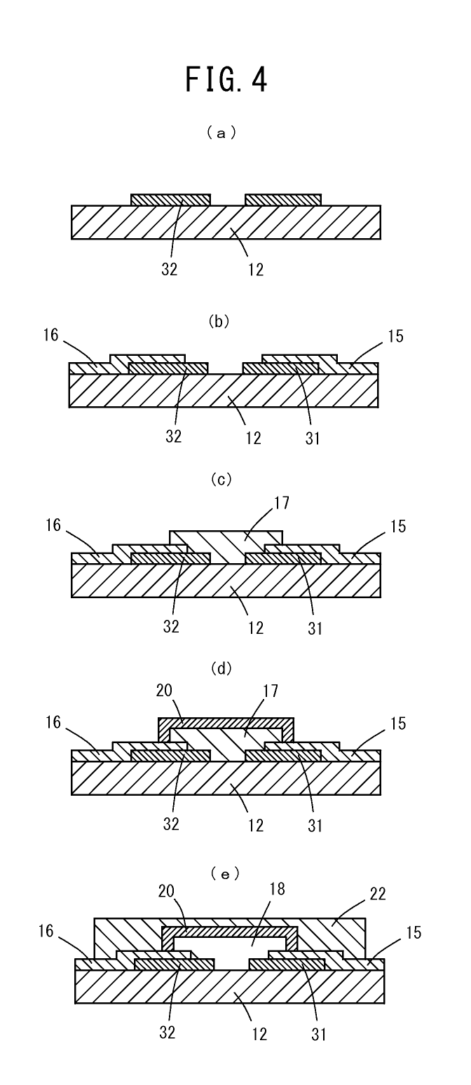

The following second embodiment of the present invention will be explained with reference to FIG. 3 and FIGS. 4(a)-(e). Herein, the same reference numerals are given to the same members as those of the embodiment described above, and the detailed description of the same members will be omitted. An electrostatic protection element 30 of this embodiment is a surface-mounted chip-type element, in which porous films 31 and 32 are formed in the center portion of the surface of the insulating substrate 12 with an interval of a gap d of around 30 to 200 μm. The porous films 31 and 32 are ceramics of aluminum oxide (Al₂O₃), the zinc oxide (ZnO) or the like and formed to be porous in a fired state. The value of the gap d between the opposing edges of the porous films 31 and 32 is set appropriately depending on an application, a discharge start voltage and the like, and the thickness of each of the porous films 31 and 32 is also set appropriately to be around 5 to 40 μm depending on the application, the discharge start voltage and the like.

As a component of the porous films 31 and 32, it is possible to use at least one type of: an oxide such as strontium oxide, titanium oxide, and magnesium oxide; a carbide such as silicon carbide, aluminum carbide, molybdenum carbide, and zirconium carbide; and a boride such as titanium boride and zirconium boride, in addition to aluminum oxide and zinc oxide.

The pair of discharge electrodes 15 and 16 are arranged to oppose each other on the surface sides of the porous films 31 and 32. The opposing interval between the edges of the discharge electrodes 15 and 16 in the center portion of the insulating substrate 12 forms a discharge gap D, which is formed to be D=around 30 to 200 μm and is wider than the gap d between the porous films 31 and 32.

The discharge gap D between the pair of the discharge electrodes 15 and 16 and the gap d between the porous films 31 and 32 are enclosed by the cavity portion 18 formed with the dome-forming layer 20. The dome-forming layer 20 is formed of glass ceramics made of alumina and a borosilicate glass component.

The whole of the dome-forming layer 20 is covered with the protection layer 22, and the protection layer 22 is formed of the same glass ceramics or an epoxy resin as that of the dome-forming layer 20. In addition, the external electrodes 23 and 24 that are each connected to the both end portions of the discharge electrodes 15 and 16, respectively, are formed by plating or the like on the both end portions of the insulating substrate 12.

Next, a method for manufacturing the electrostatic protection element 30 of this embodiment will be explained. First, a paste of a ceramics material to form the porous films 31 and 32 is produced. As described above, a material includes aluminum oxide (Al₂O₃) and zinc oxide (ZnO), and the material is mixed with an organic binder to be a paste for thick-film printing adjusted to have viscosity with which screen printing is possible.

The insulating substrate 12 is to be divided later into individual insulating substrates 12, and pastes for thick-film printing that form a plurality of pairs of porous films 31 and 32 are applied onto predetermined places on a large multiple-piece insulating substrate by screen printing, as shown in FIG. 4(a). As for an application thickness, printing is performed so that a thickness after firing is a predetermined thickness within 5 to 40 μm.

Thereafter, the insulating substrate 12 on which the paste that forms the porous films 31 and 32 is formed by printing, is fired at 1100 to 1300° C., and preferably at 1150 to 1250° C. for 0.5 to 3 hours. The firing temperature at this time is set to a temperature that is lower than the melting point of the ceramics forming the porous films 31 and 32 by 200 to 50° C., and preferably 150 to 100° C., and that can fire the porous films 31 and 32. Accordingly, a porous ceramics layer is fired. The firing temperature is set to an optimum temperature because the ceramics is not formed to be porous at a temperature close to the melting point of the ceramics while good porous ceramics is not formed at a temperature that is lower than the melting point of the ceramics by 200° C. or more. Further, the temperature should be equal to or more than the firing temperature for the discharge electrodes 15 and 16 that will be described below.

Next, by using a conductor paste such as Ag—Pd, the conductor paste that is an electrode material for the discharge electrodes 15 and 16 is formed on the large substrate of the insulating substrate 12 by screen printing as shown in FIG. 4(b). The conductor paste for the discharge electrodes 15 and 16 is formed with an opposing interval so that the discharge gap D is formed on the discharge auxiliary electrode 14 in the center portion of the insulating substrate 12. Then, firing is performed at 800 to 950° C. to form the discharge electrodes 15 and 16.

The pair of discharge electrodes 15 and 16 are applied with the resin material 17 that is a thermosetting resin material such as ethyl cellulose, PVB and the like to form the cavity portion 18 that encloses the discharge gap D and that evaporates and dissipates at 250 to 700° C., by screen printing, dispensing or the like, as shown in FIG. 4(c). Thereafter, the resin material 17 for forming the cavity portion 18 is cured at 150 to 250° C.

After the resin material 17 for forming the cavity portion 18 is cured, a paste of glass ceramics that forms the dome-forming layer 20 on the resin material 17, is formed so as to cover the whole of the resin material 17 for forming the cavity portion 18, as shown in FIG. 4(d). The glass ceramics that forms the dome-forming layer 20 is provided on the resin material 17 by screen printing. The glass ceramics paste is fired at the temperature of 600 to 850° C. to form the dome-forming layer 20 with which the cavity portion 18 is formed. At this time, first, a degreasing step of the resin material for forming the cavity portion 18 is performed at 250 to 700° C. to evaporate the resin material for forming the cavity portion 18, and thereafter fire the dome-forming layer 20.

Next, the protection layer 22 is formed of the glass ceramics or the epoxy resin so as to cover the dome-forming layer 20, and fired or cured as shown in FIG. 4(e). The firing temperature of the glass ceramics is at 500 to 850° C., and the curing temperature of the epoxy resin is 150 to 250° C.

Subsequently, by using horizontal dividing grooves formed on the large substrate, a dividing step of dividing into block units is performed in each of which a series of electrostatic protection elements 30 are laterally arranged in a row. Thereafter, the external electrodes 23 and 24 are formed, by plating or the like, on the divided surfaces of blocks separated by the dividing step and the exposed surfaces of the discharge electrodes 15 and 16 on the insulating substrate 12. Finally, each of the blocks divided and processed in the dividing step is further divided into individual pieces. Through the steps described above, the chip-type electrostatic protection element 30 is completed. A chip size at this time is, for example, 1.0 mm×0.5 mm.

In the electrostatic protection element 30 and the method for manufacturing same of this embodiment, since the porous films 31 and 32 are located in a layer under the discharge electrodes 15 and 16 and a glass component in the discharge electrodes 15 and 16 is absorbed in a number of pores in the porous films 31 and 32, it is possible to lower the resistance values of the discharge electrodes 15 and 16 and the initial (first to third) discharge voltage. Further, post-processing of the discharge electrodes 15 and 16 by laser cutting or the like is not required, and thus manufacturing costs can be reduced. In addition, since the gap d is formed between the porous films 31 and 32, film performance is not deteriorated over time like a functional film connecting the discharge electrodes 15 and 16 to each other, and stable performance can be maintained over a long period of time.

It is noted that the electrostatic protection element and the method for manufacturing same of the present invention are not limited to the embodiment described above, and the material and the component ratio of the discharge auxiliary electrode and a porous film can be set appropriately depending on a targeted discharge voltage and performance of an electronic device.

### DESCRIPTION OF REFERENCE NUMERALS

10 electrostatic protection element
12 insulating substrate
14 discharge auxiliary electrode
15, 16 discharge electrode
18 cavity portion
20 dome-forming layer
22 protection layer
23, 24 external electrode
D discharge gap

1. An electrostatic protection element, comprising:
a pair of discharge electrodes that are provided on an insulating substrate with a discharge gap of 30 to 200 μm therebetween;
a discharge auxiliary electrode, that connects the discharge electrodes to each other so as to link the discharge gap between the discharge electrodes, has a varistor function with zinc oxide as a main component, and is provided by thick-film printing; and
an insulating dome-forming layer with which a cavity portion is formed so as to cover the discharge gap, wherein:
the discharge auxiliary electrode has zinc oxide as a main component, and is made of ceramics powder including 0.7 to 10 mol % of at least two types of the respective oxides of cobalt, nickel, chromium, praseodymium, aluminum, antimony, bismuth, manganese, and titanium, and
the dome-forming layer is formed of glass ceramics, and is coated with a protection layer.

2. An electrostatic protection element, comprising:
a pair of porous films of ceramics that are provided on an insulating substrate by thick-film printing with a 30 to 200 μm gap therebetween;
a pair of discharge electrodes that are laminated on the porous films and provided with a discharge gap therebetween where the discharge gap is wider than the gap; and
an insulating dome-forming layer with which a cavity portion is formed so as to cover the discharge gap, wherein:
the dome-forming layer is formed of glass ceramics, and is coated with a protection layer.

3. The electrostatic protection element according to claim 1, wherein the glass ceramics is made of alumina and a borosilicate glass component.

4. The electrostatic protection element according to claim 2, wherein each of the porous films is made of at least one of aluminum oxide, zinc oxide, strontium oxide, titanium oxide, magnesium oxide, silicon carbide, aluminum carbide, molybdenum carbide, zirconium carbide, titanium boride, and zirconium boride.

5. A method for manufacturing an electrostatic protection element, comprising:
forming a discharge auxiliary electrode on an insulating substrate by printing and firing a paste of a material of a discharge auxiliary electrode that has a varistor function with zinc oxide as a main component, and is made of ceramics powder including 0.7 to 10 mol % of at least two types of the respective oxides of cobalt, nickel, chromium, praseodymium, aluminum, antimony, bismuth, manganese, and titanium;
printing a paste of a material of a pair of discharge electrodes on the discharge auxiliary electrode and on both end portions of the insulating substrate such that a 30 to 200 μm discharge gap overlaps with the discharge auxiliary electrode;
firing the paste at a temperature that is lower than a firing temperature of the discharge auxiliary electrode to form a pair of discharge electrodes that are laminated on the discharge auxiliary electrode with the discharge gap therebetween;
providing an insulating dome-forming layer with which a cavity portion is formed so as to cover the discharge gap; and
forming the cavity portion by providing and curing a resin material so as to cover the discharge gap between the discharge electrodes, applying a paste of glass ceramics that forms the dome-forming layer on the resin material, firing the paste at a temperature that is lower than a firing temperature of the discharge electrodes, and evaporating the resin material.

6. A method for manufacturing an electrostatic protection element, comprising:
printing, in a predetermined shape, a paste of ceramics powder that forms a pair of porous films on an insulating substrate with a 30 to 200 μm gap therebetween;
firing the paste at a temperature that is lower than the melting point of the ceramics by 100° C. or more and that allows firing to form the pair of porous films, printing a paste of a material of a pair of discharge electrodes that are provided to be laminated on the porous films with a discharge gap therebetween where the discharge gap is wider than the gap between the edges of the pair of porous films, on the porous films and on both end portions of the insulating substrate;
firing the paste at a temperature that is lower than a firing temperature of the porous films to form a pair of discharge electrodes that are laminated on the porous films with a discharge gap therebetween, and providing an insulating dome-forming layer with which a cavity portion is formed so as to cover the discharge gap; and
forming the cavity portion by providing and curing a resin material so as to cover the discharge gap between the discharge electrodes, applying a paste of glass ceramics that forms the dome-forming layer on the resin material, firing the paste at a temperature that is lower than a firing temperature of the discharge electrodes, and evaporating the resin material.

7. The electrostatic protection element according to claim 2, wherein the glass ceramics is made of alumina and a borosilicate glass component.
